(19) United States
(12) Patent Application Publication
(10) Pub. No.: US 2005/0119778 A1
(43) Pub. Date: Jun. 2, 2005

(54) CODING METHOD WITH DYNAMIC POSITIONING

(76) Inventors: Tung-Hung Tsai, Tucheng City (TW); Shyang-Li Wang, Tucheng City (TW); Shian Chin Lin, Tucheng City (TW); Shie Yu Hung, Tucheng City (TW); Chai-Chih Huang, Tucheng City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/722,523

(22) Filed: Nov. 28, 2003

(51) Int. Cl. G06F 19/00; H01L 21/66; G01R 31/00; G01R 31/26; G01R 27/28; G01R 31/14

(52) U.S. Cl. 700/121; 702/117

(57) ABSTRACT

A coding method with dynamic positioning is used in a die pick-up process. The steps include picking up one of the dies and examining the dies for classifying the grade of the dies for deposit in their exclusive bin. In the meantime, the method classifies the excusive bin for each grade of die during the process, and continues to perform the die pick-up process until all the dies are picked-up.

### BACKGROUND OF THE INVENTION

3. Field of the Invention

The present invention provides a coding method with dynamic positioning. More particularly, the dynamic positioning coding method is used in a die pick-up process. By using the dynamic positioning coding method provided in the present invention, a positioning system can effectively pick-up a die from a wafer and then put it to a bin.

4. Description of the Prior Art

In the traditional die pick-up process, the apparatus first classifies the exclusive bin for each grade of the dies. Then, it picks up all the dies from one wafer into the exclusive bin for the respective grade. Each die herein has multiple semiconductor circuit components, and the wafer has a rectangular array of a multiple-die arrangement.

Referring to FIG. 1, there is shown, a prior art die pick-up process. One of the dies 1 is picked up from a fixed position on of the wafer 2. The pick-up method can remove the die from the wafer 2 through the pick-up apparatus 3. The pick-up apparatus can be a robotic arm, and the wafer 2 can be supported by the wafer base. By the position from rotating the wafer base, the relative movement between the robotic arm and the wafer base leads the die being picked from the wafer, and then, the die is moved to the exclusive bin 4. This kind of conventional die pick-up method can easily move the wafer into the right position, particularly for large-size wafers. According to the first change of the technique development, the size of the wafer becomes larger, but the dies become more and more dense. Therefore, the distribution range in the different grades of the dies is broader. The traditional design of positioning systems, with a robotic arm trying to rotate the wafer and put the dies in the right position becomes more complicated and more difficult. This has a restriction on the equipment, and the accuracy of the die pick-up process.

Referring to FIG. 2, a flow chart of the prior art die pick-up process is shown. Using the conventional technique to pick-up from the wafer, firstly in step 501 all the die sorts on the wafer are tested, then, the sorts are classified into multiple resulting grades. For example, they range from the first grade to the twelfth grade. Further, in step 502 the N-th bin is assigned as the exclusive bin for the die of the N-th grade. For example, the first bin is for the first grade of dies. Then, in step 503 the wafer is rotated and it leads a die of the N-th grade to be positioned on the down side of the pick-up apparatus. Further, in step 504 the die of the N-th grade is picked up, and then it is put into the exclusive bin for the die of the N-th grade. Finally, in decision step 505, it is determined if all of the dies have been picked up completely. If all of the dies have been completely picked up, the die pick-up process has been implemented. However, if it is not completed, the die pick-up process will continue to be performed until all the dies have been picked-up. In addition to the grades of the dies in the wafer have a broad distribution range, a large movement range in the pick-up apparatus occurs as do other problems. Further, some unreachable dead angles will result.

### SUMMARY OF THE INVENTION

According to the above description, the present invention provides a coding method with dynamic positioning. It can effectively improve the die pick-up process. By using the dynamic positioning coding method, any one of the dies is first picked up, and tested as well as being defined as a grade for the die. Then, the die is put into a bin, and the bin is defined as the exclusive bin for the grade of the die at the same time. Then, the process continues with the dies being picked up until all of the dies are in their exclusive bins. The exclusive bins are not arranged in advance, the exclusive bins only being defined for the actual die grade distribution. This can speed up the completion of the die pick-up process and shorten the movement distance of the die pick-up process. Further, it can effectively overcome the problem of large movement distance in the pick-up apparatus as well as more complicated problems. The process of die pick-up can be accurate and more efficient.

The present invention provides a coding method with dynamic positioning. More particularly, the present invention is used in a die pick-up process. The dynamic positioning coding method does not arrange the exclusive bins in advance, but only defines the exclusive bins for the actual die grade distribution. This can quickly complete the die pick-up process. Further, it can shorten the movement distance of the pick-up apparatus. Further, it can effectively solve the problem of large movement distance in the pick-up apparatus as well as other complicated problems. Therefore, the die pick-up process can be more accurate and more efficient.

For a more complete understanding of the present invention and for further advantages thereof, reference is now made to the following description taken in conjunction with the accompanying drawing, in which:

### BRIEF DESCRIPTION OF THE DRAWINGS

FIG. 1 is a conventional die pick-up graph;

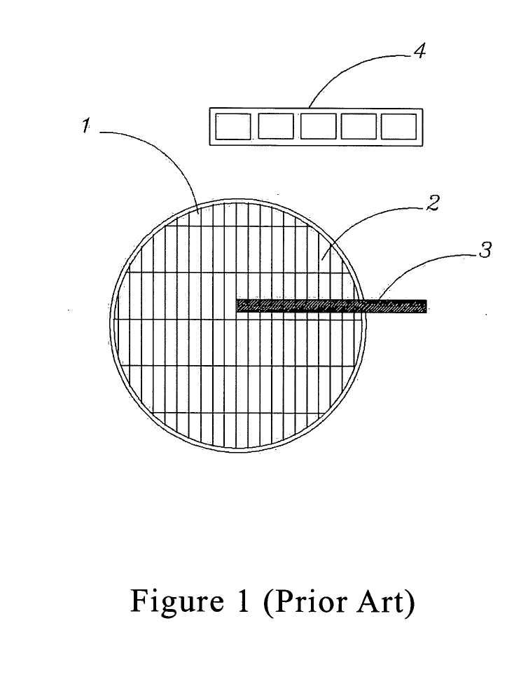

FIG. 2 is one conventional die pick-up flow chart; and

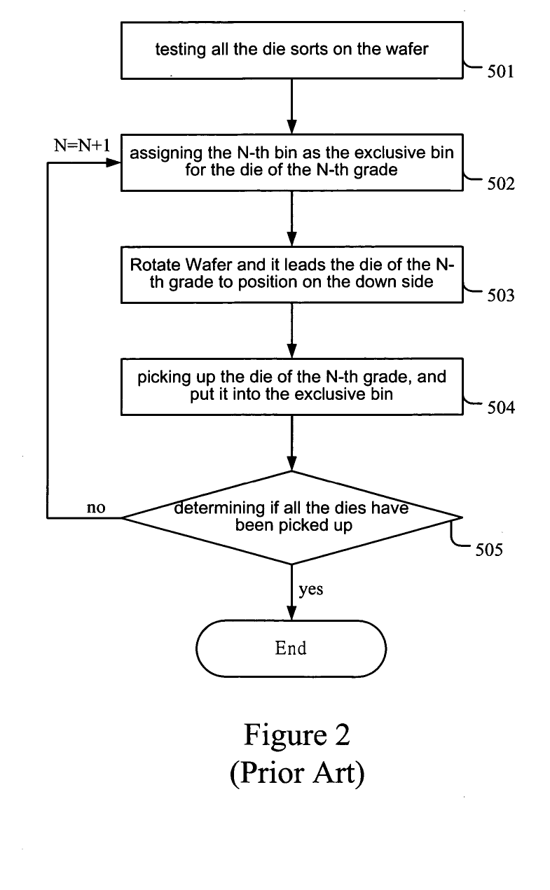

FIG. 3 is a preferred embodiment according to the present invention showing the flow chart of the dynamic positioning coding method for sorting die.

### DETAILED DESCRIPTION OF THE PREFERRED EMBODIMENTS

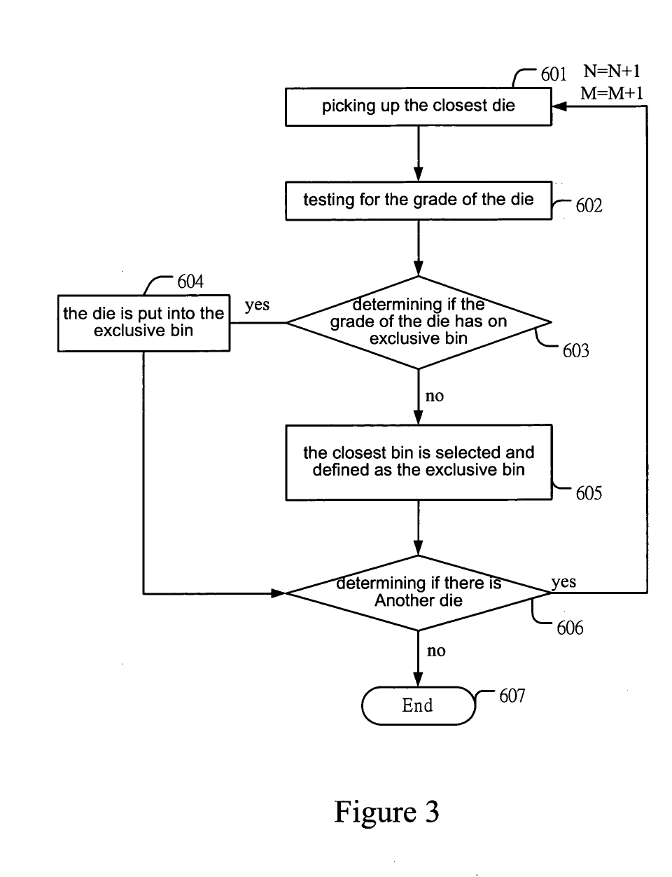

The present invention provides a coding method with dynamic positioning. More particularly, the dynamic positioning coding method is used in the die pick-up process. It uses the die pick-up step of the dynamic positioning coding method to pick up one of the dies, and then tests the die. According to the result of the die testing, it classifies the grade for the die. Further, it puts the die to one of the bins. In the meantime, the bin is classified as an exclusive bin for the grade of the die. Further, it continues to complete the pick-up process until all the dies are in their exclusive bins. The present invention only defines the exclusive bins for the actual die grade distribution thereof to quickly complete the die pick-up process. This can shorten the movement distance of the pick-up apparatus. Further, it can effectively solve the problem of the large movement of the pick-up apparatus as well as other complicated problems. Therefore, the die pick-up process can be made more accurate and more efficient. For a further description, please refer to FIG. 3. FIG. 3 is a flow chart of one of the preferred embodiments according to the present invention showing the dynamic positioning coding method for sorting dies. The dynamic positioning coding method according to the present invention is used in the die pick-up process. First, in step 601 the N-th die is picked-up by using a pick-up apparatus to perform the pick-up motion. The pick-up apparatus can be a robotic arm. Apart from this, in step 602, the grade for the N-th grain is tested. The method for testing the die can be a yield test. The result of the yield test can recognize the condition of the defect in the die and treat it as a classification standard. By this standard, the dies can be divided into multiple grades. The expression for the grade can be a natural number, an integral or a defect percentage. Then, in step 603 it is determined if the grade of the die has an exclusive bin. If there is an exclusive bin, the N-th die is put into the N-th exclusive bin of that grade in step 604. If there is no exclusive bin, then, in step 605 the M-th bin is defined as an exclusive bin for the N-th die or a die with the same grade. M here is a natural number. Further, in step 606 the pick-up apparatus goes back and checks if there are any un-picked dies. If there are no more dies to pick-up, then, the pick-up process is completed in step 607. If there is still a die to be picked-up, then, steps 601-606 are repeated to continue the pick-up process.

For example, first, the closest die is picked-up in step 601, and tested in step 602. The tested grade in step 602 is the first grade, and in step 603 it is determined if the grade of the die has an exclusive bin for the first grade. If so, the die is put into the exclusive bin for the first grade in step 604. If not, then, the closest bin is selected and defined as the exclusive bin for the grade of the die in step 605. Further, in step 606 it is determined if there is any more dies. If there is still another die, the process goes back to the first step for picking up the N-th die and continues until all of the dies are picked-up. According to the above description, the present invention provides a dynamic positioning coding method. It does not arrange the exclusive bins in advance, but only defines the exclusive bins for the actual die grade distribution. This can quickly complete the die pick-up process and shorten the movement distance of the die pick-up apparatus. Further, it can effectively overcome the problem of large movement distance in the pick-up apparatus as well as more complicated problems. The process of die pick-up can be accurate and more efficient.

Although the present invention has been described in detail, with respect to alternate embodiments, various changes and modifications may be suggested to one skilled in the art, and it should be understood that various changes, suggestions, and alternations can be made hereto without departing from the spirit and scope of the invention as defined by the appended claims.

1. A method of dynamic positioning coding for a die pick-up process, comprising the steps of;
a. picking up a die;
b. testing said die to establish a grade thereof;
c. determining if a bin has been assigned to said established grade and if said bin has not been assigned, assigning said established grade to correspond with a closest available bin; and
d. picking up said tested die and depositing said tested die into said assigned bin.

2. The method of the claim 1, wherein further comprising the step of:
e. determining whether there is another die to be picked up and repeating steps a-e if there is another die.

3-8. (canceled)
